(19) United States
(12) Patent Application Publication
(10) Pub. No.: US 2014/0111938 A1
(43) Pub. Date: Apr. 24, 2014

(54) COOLING PLATE WITH COOLING PATTERNS AND METAL CASING USING SAME

(71) Applicant: HON HAI PRECISION INDUSTRY CO., LTD., New Taipei (TW)

(72) Inventor: WEI-CHIH HUNG, New Taipei (TW)

(73) Assignee: HON HAI PRECISION INDUSTRY CO., LTD., New Taipei (TW)

(21) Appl. No.: 14/059,511

(22) Filed: Oct. 22, 2013

(30) Foreign Application Priority Data
Oct. 24, 2012 (TW) 101139209

(51) Int. Cl. H05K 5/02; H05K 5/04

(52) U.S. Cl. CPC H05K 5/0213; H05K 5/04
USPC 361/692

(57) ABSTRACT

A metal cooling plate functioning includes a plurality of through cooling patterns. Each cooling pattern includes a ventilation through hole and two “V”-shaped annular grooves, each annular groove surrounding the outside the ventilation through hole. Each side of the cooling plate defines the “V”-shaped annular groove, where the annular grooves being paired are directly opposing each other. Areas of the metal cooling plate directly between respective bottoms of the opposing grooves form an annular plastic zone in which electrical resistance is higher than a resistance of the metal base at all other areas.

### BACKGROUND

1. Technical Field

The present disclosure generally relates to a cooling plate with cooling patterns, and particularly to a casing using the cooling plate.

2. Description of Related Art

Electromagnetic interference (EMI) can affect electronic devices, and the electronic devices can use metal casings to shield against electromagnetic radiation. However, because the electronic devices may also radiate vast amounts of heat, if the metal casings overheat, performance and reliability of the electronic devices may suffer. Thus, the metal casings often have a plurality of ventilation through holes to expend heat, but these holes also allow electromagnetic radiation to leak out to the outside of the metal casings.

What is needed, therefore, is a means which can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of a cooling plate according to a first embodiment of the disclosure.

FIG. 2 is a partial, exploded, isometric view of the cooling plate of FIG. 1.

FIG. 3 is an enlarged, isometric view of a circled portion III of the cooling plate of FIG. 2.

FIG. 4 is an isometric view of a metal casing using the cooling plate of FIG. 1.

FIG. 5 is a partial, exploded, isometric view of a cooling plate according to a second embodiment of the disclosure.

### DETAILED DESCRIPTION

Reference will be made to the drawings to describe various embodiments.

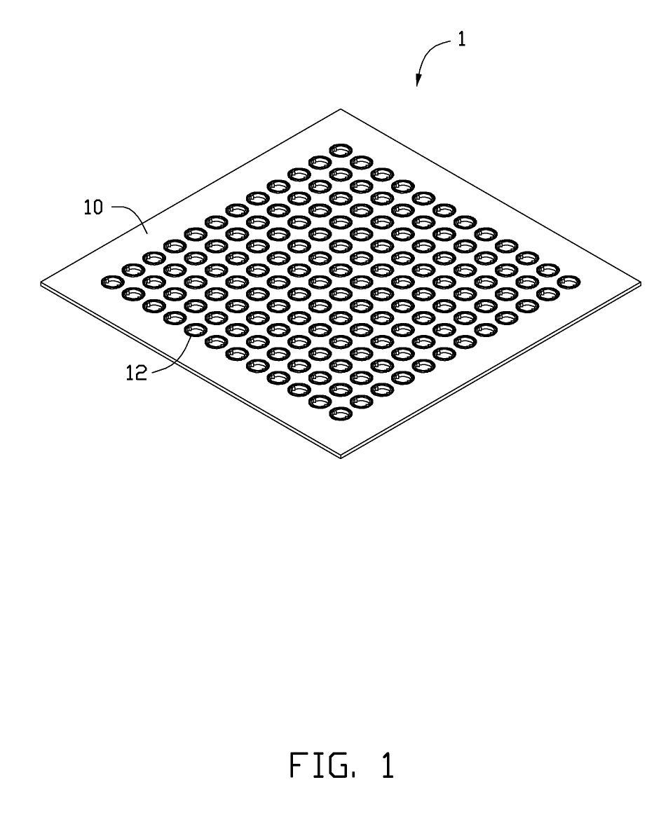

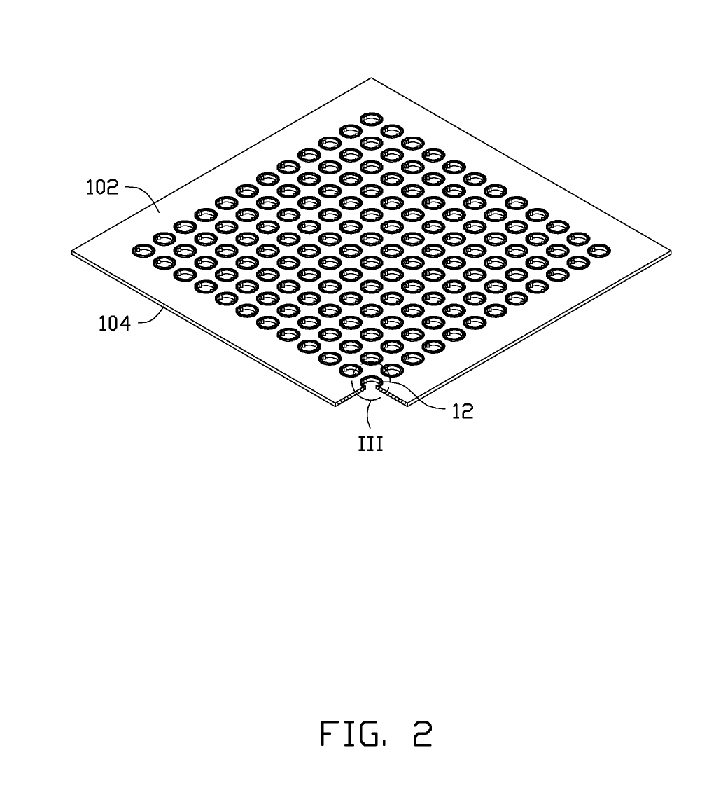

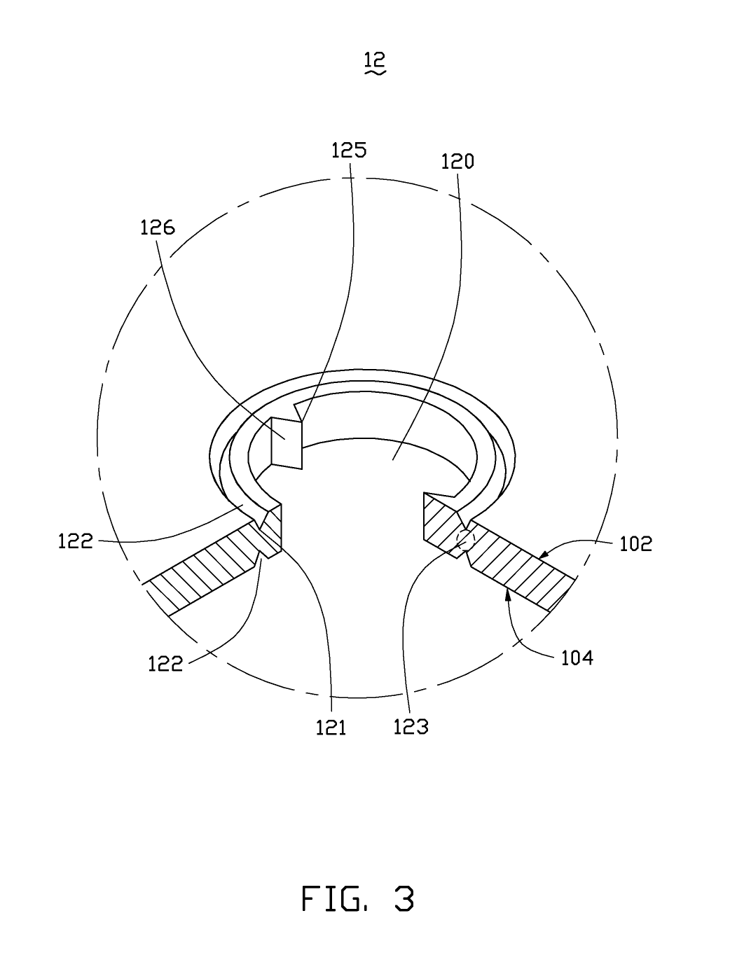

In FIGS. 1-3, in a first embodiment, a cooling plate (heat sink) 1 includes a metal base 10, and the metal base 10 includes a first surface 102, a second surface 104 opposite to the first surface 102 and a plurality of cooling patterns 12. Distance between the first surface 102 and the second surface 104 defines a thickness of the metal base 10. The cooling patterns 12 penetrate through the metal base 10. In the embodiment, the cooling patterns 12 are arranged in a predetermined pattern, such as a matrix pattern.

Each cooling pattern 12 includes a ventilation through hole 120, at least one annular groove 122, and at least one protrusion 126. In this embodiment, each cooling pattern 12 includes two annular grooves 122 and two protrusions 126. One of the two annular grooves 122 is defined at the first surface 102, and the other one of the two annular grooves 122 is defined at the second surface 104. The ventilation through hole 120 passes through the first surface 102 and the second surface 104 of the metal base 10. Each annular groove 122 surrounds outside the ventilation through hole 120. A width of each annular groove 122 at a top of the annular groove 122 is greater than a width of each annular groove 122 at a bottom of the annular groove 122, thereby forming a first tip 121 at the bottom of each annular groove 122. The first tips 121 of the two annular grooves 122 oppose each other. The two protrusions 126 attach to a sidewall of the ventilation through hole 120 and are diametrically opposite each other, at opposite sides of the sidewall of the ventilation through hole 120. Each protrusion 126 includes a second tip 125 extending towards a center of the ventilation through hole 120. In this embodiment, the ventilation through hole 120 is circular, the two annular grooves 122 surround the outside the circumference of the ventilation through hole 120, and the cross-section of the annular groove 122 is V-shaped.

The two annular grooves 122 of the metal base 10 can be formed by punching process using a punching die. Plastic deformations of the metal base 10 caused by tip stress of the punching die is between the first tips 121 of the two annular grooves 122, thereby forming a annular plastic zone 123 at the metal base 10, and the annular plastic zone 123 is sandwiched directly between the first tips 121 of two annular grooves 122. A resistance of the annular plastic zone 123 of the metal base 10 is higher than a resistance of the metal base 10 in other areas besides the annular plastic zone 123. Alternatively, annular plastic zone 123 of the metal base 1 can also be formed by a cold-working treatment process or a heat treatment process.

Resistance of the metal base 10 at the annular plastic zone 123 is higher than a resistance of the metal base 10 in other areas, thus, any electric current which is present moves to an area which has a lower electrical resistance. Thus, when electromagnetic radiation passes through the ventilation through holes 120, an induced current is generated in the areas of the metal base 10 which are surrounded by the annular plastic zone 123. Correspondingly, an induced magnetic field is generated by the induced current, with a direction of the induced magnetic field opposite to a direction of the electromagnetic radiation passing through the ventilation through holes 120. The induced magnetic field offsets and opposes part of the electromagnetic radiation passed through the ventilation through holes 120, thereby canceling at least some of the electromagnetic radiation passing through the ventilation through holes 120.

Since a tip of a body tends to gather free electrons, the second tip 125 of the at least one protrusion 126 tends to gather free electrons. The free electrons increase the induced current and the strength of the induced magnetic field. Accordingly, the electromagnetic radiation passing through the ventilation through holes 120 is further decreased.

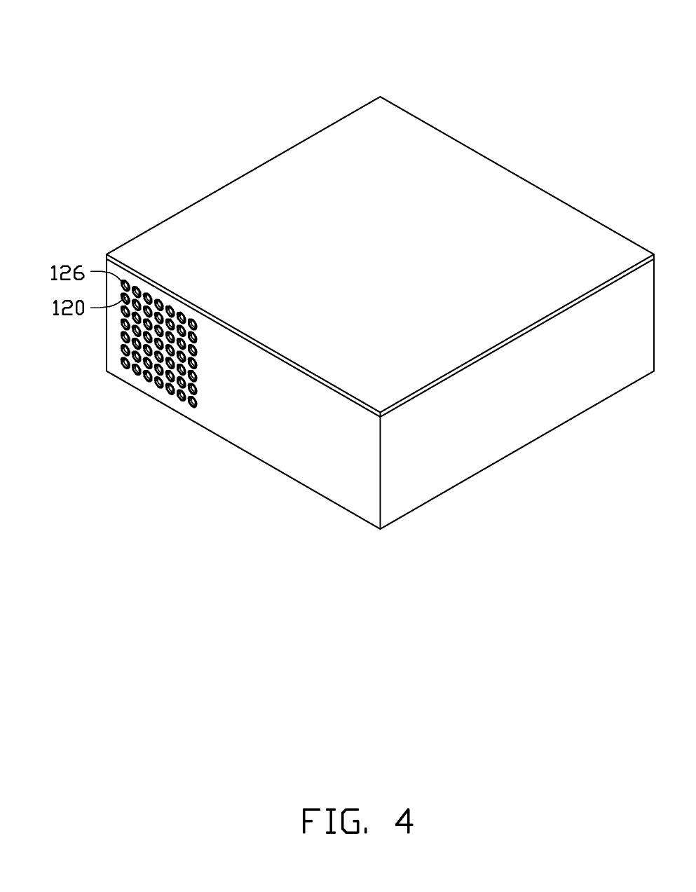

When an electronic device uses a metal casing includes the cooling plate 1 (see FIG. 4), where the ventilation through holes 120 have at least one protrusion 126, an electric potential difference between the metal casing and the local electrostatic charge is higher than an electric potential difference between an interior circuit board of the electronic device in the metal casing and the local electrostatic charge. This means that the metal casing provides a higher electric potential difference. In the event that the electric potential difference become too high, a high voltage arc may occur at the metal casing releasing the electrostatic charges, therefore effectively protecting the interior circuit board of the electronic device from serving as a ground connection.

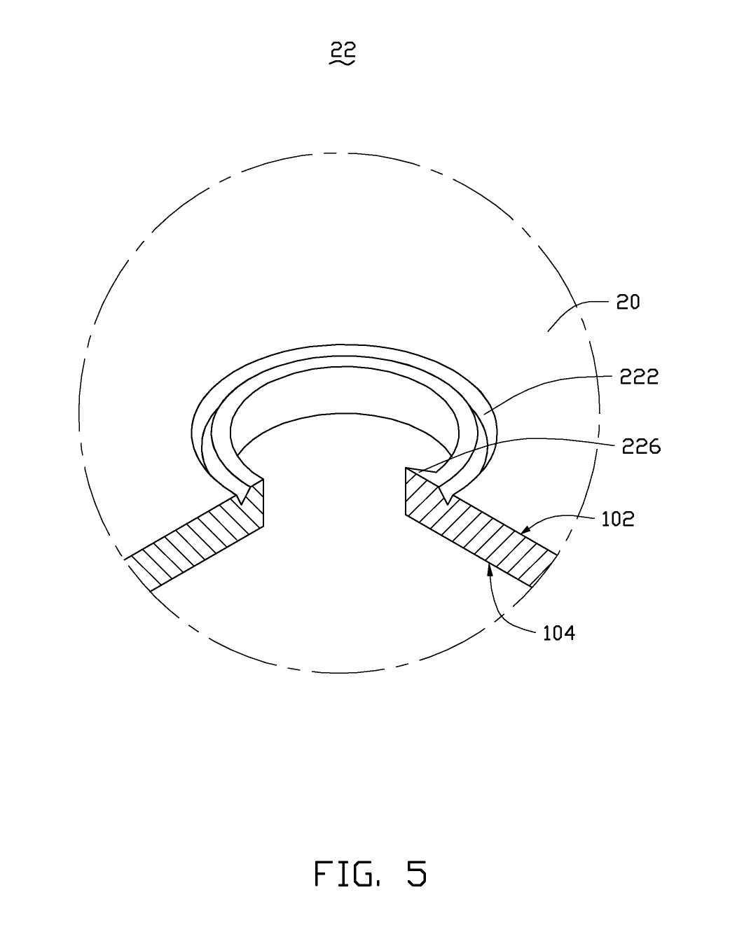

In FIG. 5, a cooling pattern 22 of the cooling plate is shown, according to a second embodiment of the present disclosure. The structure of the cooling pattern 22 is similar to the structure of the cooling pattern 12, except that the cooling pattern 22 has only one annular groove 222, the annular groove 222 being defined at the first surface 102, and the sidewall of the ventilation through hole supports only one protrusion 226. A region of the metal base 20 corresponding to a first tip of the annular groove 222 forms the annular plastic zone. Alternatively, an annular groove 222 can also be defined at the second surface 104.

It is believed that the present embodiments and their advantages will be understood from the foregoing description, and it will be apparent that various changes may be made thereto without departing from the spirit and scope of the description or sacrificing all of their material advantages, the examples hereinbefore described merely being exemplary embodiments.

What is claimed is:

1. A cooling plate, comprising a metal base, the metal base comprising:
a first surface;
a second surface opposite to the first surface;
a plurality of cooling patterns, each cooling pattern comprising a ventilation through hole passing through the first and the second surfaces and at least one annular groove, a vertical distance between the first surface and the second surface defining a thickness of the metal base, and each annular groove surrounding the ventilation through hole;
wherein at least one of the first surface and the second surface defines the at least one annular groove, a width of each annular groove at a top of the annular groove is less than a width of each annular groove at a bottom of the annular groove, thereby forming a first tip at the bottom of each annular groove, a region of the metal base corresponding to the first tip forms an annular plastic zone which has a resistance higher than a resistance of the metal base in other areas besides the annular plastic zone.

2. The cooling plate of claim 1, wherein each cooling pattern comprises at least one protrusion attached to a sidewall of the ventilation through hole, and the at least one protrusion includes a second tip extending towards a center of the ventilation through hole.

3. The cooling plate of claim 2, wherein each cooling pattern comprises two protrusions, the two protrusions are located at opposite sides of the sidewall of the ventilation through hole, and the second tips of the protrusions face each other.

4. The cooling plate of claim 1, wherein each cooling pattern comprises two annular grooves, one of the two annular grooves is located at the first surface, and the other one of the two annular grooves is located at the second surface, the first tips of the two annular grooves face each other.

5. The cooling plate of claim 4, wherein the annular plastic zone is sandwiched between the first tips of the two annular grooves.

6. The cooling plate of claim 1, wherein the ventilation through hole is circular, each annular groove is surrounded outside the circumference of the ventilation through hole

7. The cooling plate of claim 6, wherein the cross section of each annular groove is V-shaped.

8. A metal casing, comprising:
a metal base including a first surface and a second surface opposite to the first surface; and
a plurality of cooling patterns defined in the metal base, each cooling pattern comprising a ventilation through hole passing through the first and the second surfaces and at least one annular groove, a vertical distance between the first surface and the second surface serving as a thickness of the metal base, and each annular groove surround an outside of the ventilation through hole;
wherein at least one of the first surface and the second surface defines the at least one annular groove, a width of each annular groove at a top of the annular groove is less than a width of each annular groove at a bottom of the annular groove, thereby forming a first tip at the bottom of each annular groove, a region of the metal base corresponding to the first tip forms an annular plastic zone which has a resistance higher than a resistance of the metal base in other areas besides the annular plastic zone.

9. The metal casing of claim 8, wherein each cooling pattern comprises at least one protrusion attached to a sidewall of the ventilation through hole, and the at least one protrusion includes a second tip extending towards a center of the ventilation through hole.

10. The metal casing of claim 9, wherein each cooling pattern comprises two protrusions, the two protrusions are located at opposite sides of the sidewall of the ventilation through hole, and the second tips of the protrusions face each other.

11. The metal casing of claim 8, wherein each cooling pattern comprises two annular grooves, one of the two annular grooves is located at the first surface, and the other one of the two annular grooves is located at the second surface, the first tips of the two annular grooves face each other.

12. The metal casing of claim 11, wherein the annular plastic zone is sandwiched between the first tips of the two annular grooves.

13. The metal casing of claim 8, wherein the ventilation through hole is circular, each annular groove is surrounded outside the circumference of the ventilation through hole

14. The metal casing of claim 13, wherein the cross section of each annular groove is V-shaped.
